(19) United States
(12) Patent Application Publication
(10) Pub. No.: US 2026/0360614 A1
(43) Pub. Date: Nov. 12, 2026

(54) MAGNETIC ELEMENT AND CIRCUIT BOARD INCLUDING SAME

(71) Applicant: LG INNOTEK CO., LTD., Seoul (KR)

(72) Inventors: Yonghwan KIM, Seoul (KR); Biyi KIM, Seoul (KR); Suekyung OH, Seoul (KR)

(21) Appl. No.: 19/139,705

(22) PCT Filed: Dec. 15, 2023
(86) PCT No.: PCT/KR2023/020809

§ 371 Date: Jun. 16, 2025

(30) Foreign Application Priority Data
Dec. 16, 2022 (KR) 10-2022-0177352

(51) Int. Cl. H01F 27/32; H01F 27/24; H05K 1/181

(52) U.S. Cl. CPC H01F 27/325; H01F 27/24; H05K 1/181; H05K 2201/1003

(57) ABSTRACT

A magnetic element according to an embodiment comprises: a core part comprising an upper core and a lower core; a first coil part and a second coil part; and a molding part disposed on the outer surface of the second coil part. The first coil part comprises: a first bobbin having a first hollow portion through which the central leg of the core part passes, the first bobbin being at least partially accommodated in the core part; a first coil disposed in a first accommodation space of the first bobbin; and a first pin connected to the first coil. The second coil part comprises: a second bobbin having a second hollow portion in which the first bobbin is at least partially accommodated, the second bobbin being disposed outside the first bobbin; a second coil disposed in a second accommodation space of the second bobbin; and a second pin connected to the second coil. The second bobbin comprises: a core region that overlaps the core part in the vertical direction; a non-core region that does not overlap the core part in the vertical direction; and a groove formed in the non-core region.

### TECHNICAL FIELD

Embodiments relate to a magnetic element and a circuit board including the same.

### BACKGROUND ART

Various coil components, such as a transformer or a line filter, are mounted in a power supply unit of an electronic device.

A transformer may be included in electronic devices for various purposes. For example, a transformer may be used to perform an energy transfer function of transferring energy from one circuit to another. In addition, a transformer may be used to perform a voltage-boosting or voltage-reducing function of changing the magnitude of voltage. Furthermore, since a transformer exhibits only inductive coupling between primary and secondary windings and does not directly form any DC path, the transformer may be used to block direct current and pass alternating current or to provide insulation between two circuits.

FIG. 1 is an exploded perspective view showing an example of the configuration of a general transformer.

Referring to FIG. 1, a general transformer 10 includes a core unit including an upper core 11 and a lower core 12 and includes a secondary coil 13 and a primary coil 14 disposed between the cores 11 and 12. Generally, the secondary coil 13 is composed of a plurality of conductive metal plates, and the primary coil 14 is formed by winding a conductive wire. In some configurations, a bobbin (not shown) may be disposed between the upper core 11 and the lower core 12.

In the transformer shown in FIG. 1, the primary coil and the secondary coil overlap each other in a vertical direction. When a conductive wire is used instead of the conductive metal plates for the secondary coil, the primary coil and the secondary coil may be disposed to overlap each other in a horizontal direction.

However, when a plurality of different coils is disposed, such as in a transformer, there is a minimum required insulation distance between the coils or between the coils and the core depending on the requirements of the circuit in which the corresponding magnetic element is disposed. However, when the plurality of different coils is disposed in the horizontal direction, the coils need to be horizontally spaced apart from each other to secure the insulation distance, which increases the planar area of the magnetic element and limits miniaturization thereof. To overcome this, a molding part is formed in the transformer. In this case, depending on the position of an injection port through which an insulating filler is injected to form the molding part, the transformer may become vulnerable to surges, and related studies are currently underway.

### DISCLOSURE

### Technical Problem

A technical task of the embodiments is to provide a magnetic element that is robust against surges and a circuit board including the same.

The technical tasks of the present disclosure are not limited to the above-mentioned technical tasks, and other technical tasks not mentioned herein will be clearly understood by those skilled in the art from the following description.

### Technical Solution

A magnetic element according to an embodiment may include a core unit including an upper core and a lower core, a first coil unit and a second coil unit, each being at least partially accommodated between the upper core and the lower core, and a molding part disposed on an outer surface of the second coil unit. The first coil unit may include a first bobbin including a first cavity formed therein to allow a center leg of the core unit to pass therethrough, the first bobbin being at least partially accommodated inside the core unit, a first coil disposed in a first accommodation space in the first bobbin, and a first pin connected to the first coil. The second coil unit may include a second bobbin including a second cavity formed therein to accommodate at least a portion of the first bobbin, the second bobbin being disposed outside the first bobbin, a second coil disposed in a second accommodation space in the second bobbin, and a second pin connected to the second coil. The second bobbin may include a core area overlapping the core unit in a vertical direction, a non-core area not overlapping the core unit in the vertical direction, and a recess formed in the non-core area.

In an example, the recess may be formed in a side surface of the non-core area.

In an example, the non-core area may include a first non-core area adjacent to one side of the core unit and connected to the second pin and a second non-core area adjacent to the opposite side of the core unit and connected to the first pin, and the recess may include at least one of a first recess disposed in the first non-core area or a second recess disposed in the second non-core area.

In an example, each of the first recess and the second recess may include a plurality of recesses spaced apart from each other.

In an example, the first recess and the second recess may be disposed to face each other in an oblique direction on a plane.

In an example, a first path defining the shortest distance may be defined on a plane along an outer surface of the second bobbin from a first point to a second point, the first point being an outer point of a boundary between the core area and the non-core area, and the second point being a point defined by outward protrusion of the second pin from the second bobbin. The first recess may be disposed on the first path at a position closer to the second point than to the first point.

In an example, a first path defining the shortest distance may be defined on a plane along an outer surface of the second bobbin from a first point to a second point, the first point being an outer point of a boundary between the core area and the non-core area, and the second point being a point defined by outward protrusion of the second pin from the second bobbin. The first recess may be disposed on the first path at a position spaced apart from the first point by at least half of the length of the first path.

In an example, the length of the first path may be 8 mm or greater. In this case, each of a distance from the first point to the first recess along the first path and a distance from the first recess to the second point along the first path may be 4 mm or greater.

In an example, the recess may be disposed on a surface of the second bobbin facing the protruding direction of the second pin.

In an example, the first recess may be formed in an outer surface or an upper surface of the second bobbin.

A circuit board including a magnetic element according to another embodiment may include a substrate and a magnetic element disposed on the substrate. The magnetic element may include a core unit including an upper core and a lower core, a first coil unit and a second coil unit, each being at least partially accommodated between the upper core and the lower core, and a molding part disposed on an outer surface of the second coil unit. The first coil unit may include a first bobbin including a first cavity formed therein to allow a center leg of the core unit to pass therethrough, the first bobbin being at least partially accommodated inside the core unit, a first coil disposed in a first accommodation space in the first bobbin, and a first pin connected to the first coil. The second coil unit may include a second bobbin including a second cavity formed therein to accommodate at least a portion of the first bobbin, the second bobbin being disposed outside the first bobbin, a second coil disposed in a second accommodation space in the second bobbin, and a second pin connected to the second coil. The second bobbin may include a core area overlapping the core unit in a vertical direction and a non-core area not overlapping the core unit in the vertical direction, the non-core area including a resin injection port formed therein.

In an example, the resin injection port may include a shape of a recess, a hole, or a protrusion.

In an example, the resin injection port may be formed with a surface roughness greater than the surface roughness of a surrounding region on an outer surface of the molding part.

### Advantageous Effects

The magnetic element and the circuit board including the same according to the embodiments may be made robust against surges by setting the position of a resin injection port.

The effects achievable through the present disclosure are not limited to the above-mentioned effects, and other effects not mentioned herein will be clearly understood by those skilled in the art from the following description.

### DESCRIPTION OF DRAWINGS

FIG. 1 is an exploded perspective view showing an example of the configuration of a general transformer.

FIG. 2A is a plan view of a transformer according to an embodiment, and FIG. 2B is a plan view of the transformer shown in FIG. 2A with a core unit removed.

FIG. 3A is a plan view of a transformer according to another embodiment, and FIG. 3B is a plan view of the transformer shown in FIG. 3A with a core unit removed.

FIG. 4 is a cross-sectional view taken along line I-I′ of the transformers shown in FIGS. 2A and 3A according to the embodiments.

FIG. 5 is a perspective view of an embodiment of the first coil unit shown in FIG. 2A.

FIG. 6 is a perspective view of an embodiment of the second coil unit shown in FIG. 2A.

FIG. 7 is a view showing portion “A” in FIG. 4 in an enlarged manner.

FIG. 8 is a view showing portion “B” in FIG. 3A in an enlarged manner.

FIG. 9 is an exploded side view of the transformer according to the above-described embodiment.

FIGS. 10A to 10D are side views showing processes of manufacturing the transformer according to an embodiment.

FIG. 11 is a side view of a circuit board according to an embodiment.

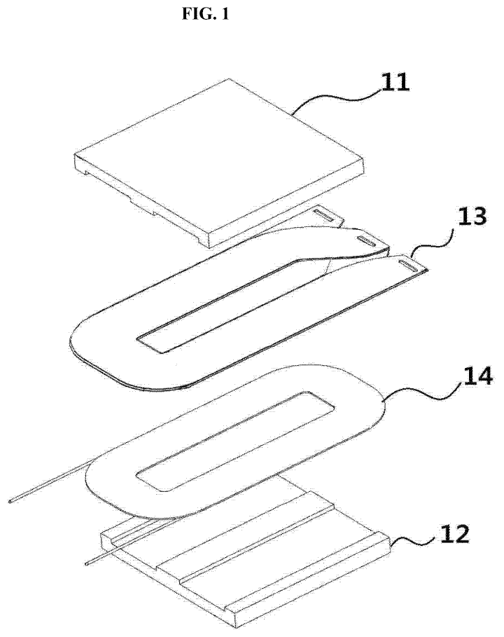

### BEST MODE

The present disclosure will now be described more fully hereinafter with reference to the accompanying drawings, in which various embodiments are shown. The examples, however, may be embodied in many different forms and should not be construed as being limited to the embodiments set forth herein. It is to be understood that the present disclosure covers all modifications, equivalents, and alternatives falling within the scope and spirit of the present disclosure.

While ordinal numbers including “second”, “first”, etc. may be used to describe various components, they are not intended to limit the components. These expressions are used only to distinguish one component from another component. For example, a second element could be termed a first element, and, similarly, a first element could be termed a second element, without departing from the scope of the present disclosure. As used herein, the term “and/or” includes any and all combinations of one or more of the associated listed items.

It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

In the description of the embodiments, it will be understood that when an element, such as a layer (film), a region, a pattern or a structure, is referred to as being “on” or “under” another element, such as a substrate, a layer (film), a region, a pad or a pattern, the term “on” or “under” means that the element is “directly” on or under another element or is “indirectly” formed such that an intervening element may also be present. It will also be understood that criteria of on or under is on the basis of the drawing. In addition, the thickness or size of a layer (film), a region, a pattern or a structure shown in the drawings may be exaggerated, omitted or schematically drawn for the clarity and convenience of explanation, and may not accurately reflect the actual size.

The terminology used herein is for the purpose of describing particular embodiments only and is not intended to be limiting of exemplary embodiments of the disclosure. As used herein, the singular forms are intended to include the plural forms as well, unless the context clearly indicates otherwise. It will be further understood that the term “include” or “have”, when used herein, specifies the presence of stated features, integers, steps, operations, elements, components, or combinations thereof, but do not preclude the presence or addition of one or more other features, integers, steps, operations, elements, components, or combinations thereof.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

Hereinafter, a magnetic element and a circuit board including the same according to embodiments will be described using the Cartesian coordinate system, but the embodiments are not limited thereto. That is, according to the Cartesian coordinate system, the x-axis, the y-axis, and the z-axis are perpendicular to each other, but the embodiments are not limited thereto. That is, the x-axis, the y-axis, and the z-axis may intersect each other obliquely rather than being perpendicular to each other. In addition, for convenience of description, the +x-axis direction or the −x-axis direction will be referred to as a “second direction”, the +y-axis direction or the −y-axis direction will be referred to as a “first direction”, the +z-axis direction or the −z-axis direction will be referred to as a “vertical direction”, and at least one of the first or second direction will be referred to as a “horizontal direction”.

Hereinafter, a transformer will be described in detail as an example of a magnetic element according to an embodiment with reference to the accompanying drawings.

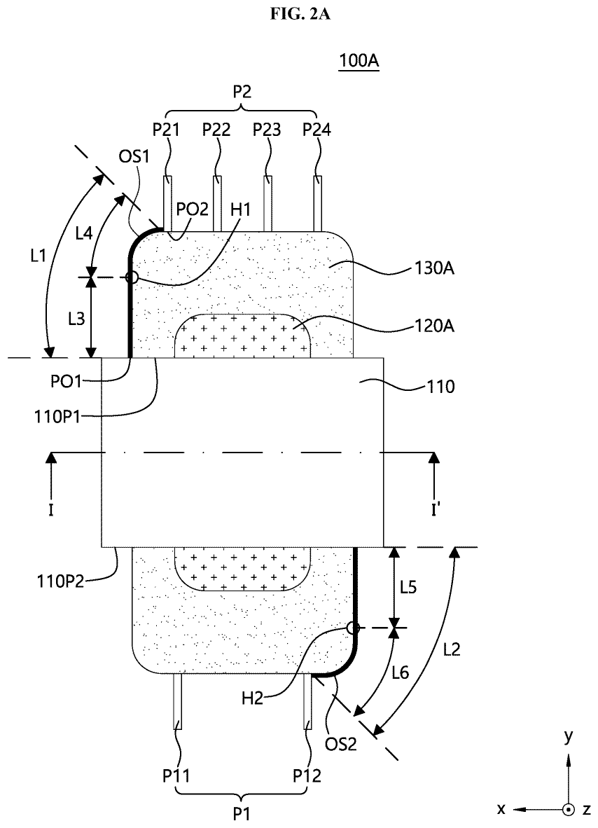

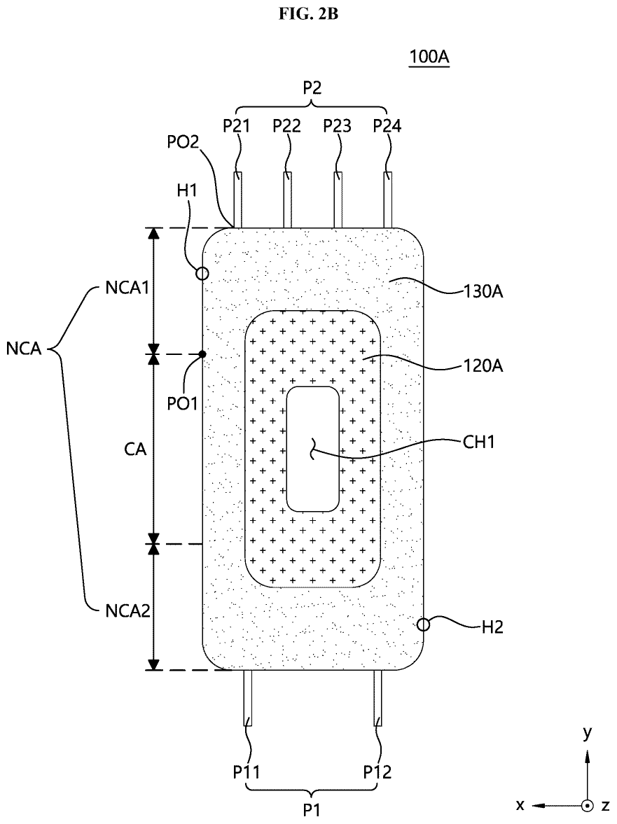

FIG. 2A is a plan view of a transformer 100A according to an embodiment, and FIG. 2B is a plan view of the transformer 100A shown in FIG. 2A with the core unit 110 removed.

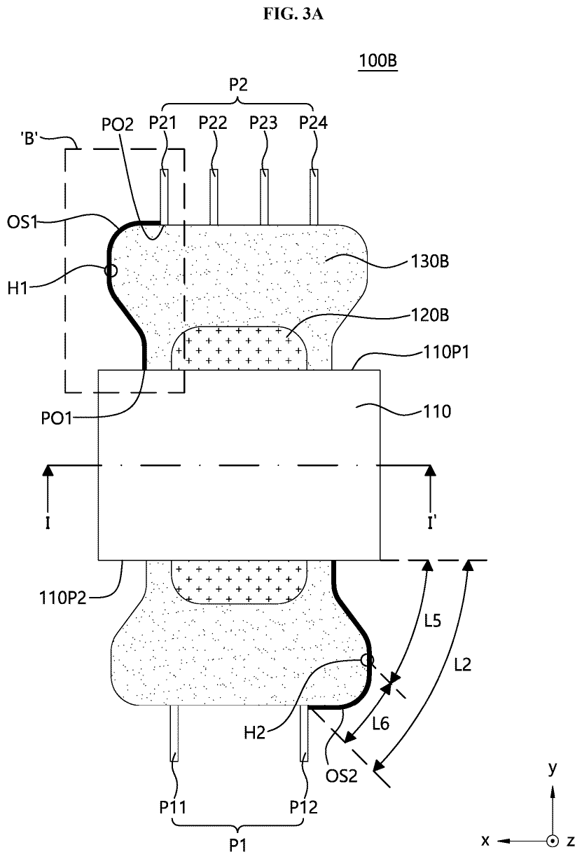

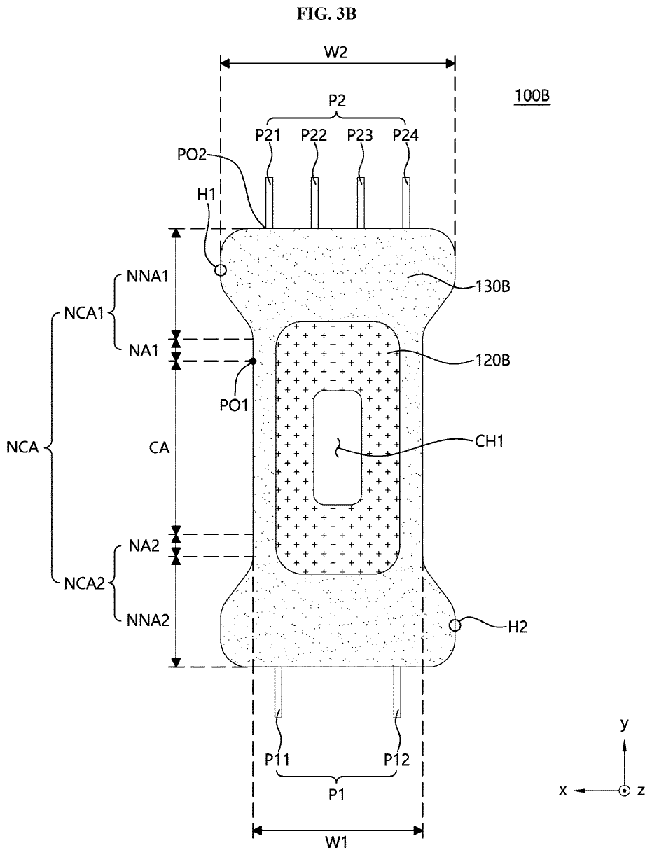

FIG. 3A is a plan view of a transformer 100B according to another embodiment, and FIG. 3B is a plan view of the transformer 100B shown in FIG. 3A with the core unit 110 removed.

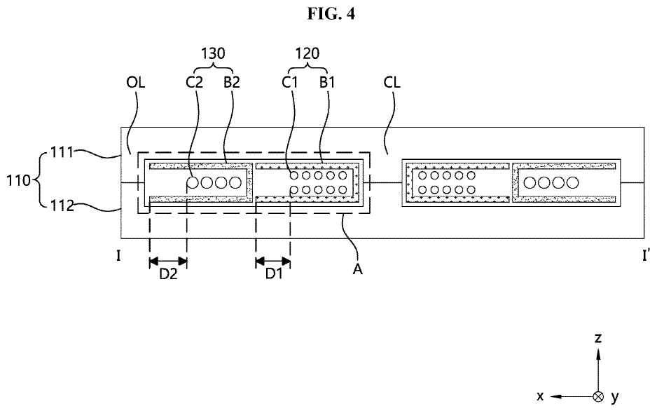

FIG. 4 is a cross-sectional view taken along line I-I′ of the transformers 100A and 100B shown in FIGS. 2A and 3A according to the embodiments.

Referring to FIGS. 2A to 4, the transformer 100A or 100B according to the embodiment may include a core unit 110, a first coil unit 120 (120A or 120B), and a second coil unit 130 (130A or 130B).

The core unit 110 may have the characteristics of a magnetic circuit and thus may act as a path for magnetic flux. The core unit 110 may include an upper core 111 coupled at an upper position and a lower core 112 coupled at a lower position. The two cores 111 and 112 may be formed to be symmetrical or asymmetrical with each other in the vertical direction. However, for convenience of explanation, the following description is provided based on the assumption that the two cores are vertically symmetrical.

Each of the upper core 111 and the lower core 112 may include a body portion having a flat plate shape and a plurality of leg portions protruding from the body portion in the vertical direction and extending in a predetermined direction. The plurality of leg portions may include two outer legs OL extending in one axis direction (e.g., the first direction) and spaced apart from each other in another axis direction (e.g., the second direction) on a plane and one center leg CL disposed between the two outer legs.

When the upper core 111 and the lower core 112 are coupled to each other in the vertical direction, the outer legs and the center leg of the upper core 111 may face the outer legs and the center leg of the lower core 112, respectively. In this case, a gap of a predetermined distance (e.g., 10 μm to 200 μm, without being necessarily limited thereto) may be defined between at least one pair among the pairs of outer legs and the pair of center legs, which face each other. FIG. 4 illustrates a configuration in which the gap is 0.

In addition, each of the upper core 111 and the lower core 112 may include a magnetic material, such as iron or ferrite. However, the disclosure is not necessarily limited thereto.

Each of the first coil unit 120 and the second coil unit 130 may be at least partially accommodated between the upper core 111 and the lower core 112.

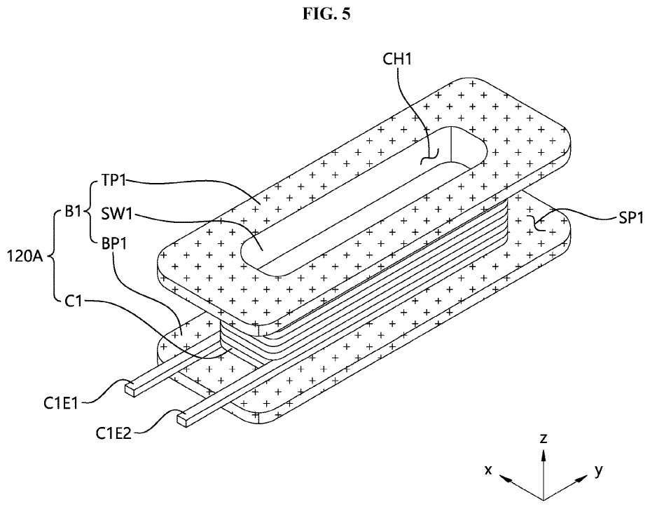

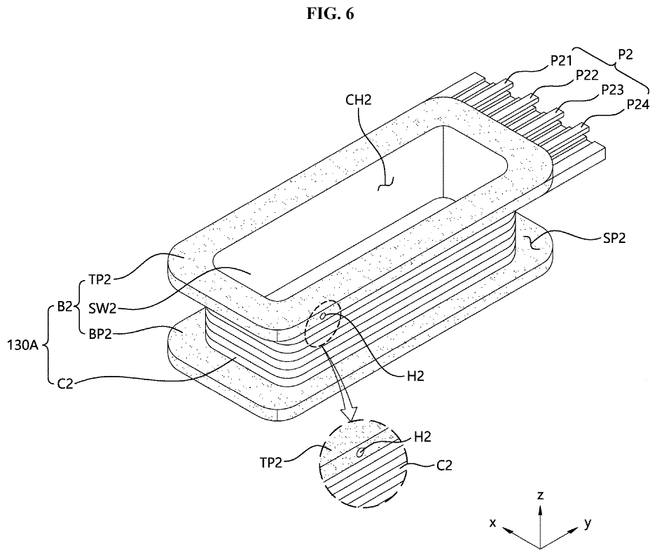

FIG. 5 is a perspective view of an embodiment of the first coil unit 120A shown in FIG. 2A, and FIG. 6 is a perspective view of an embodiment of the second coil unit 130A shown in FIG. 2A.

Hereinafter, only the first and second coil units 120A and 130A shown in FIG. 2A will be described. However, the following description may also be applied to the first and second coil units 120B and 130B shown in FIG. 3A. This is because, as shown in FIGS. 2B and 3B, the first and second coil units 120B and 130B have shapes similar to those of the first and second coil units 120A and 130A, except for differences in the shapes of non-core areas NCA1 and NCA2.

The first coil unit 120A may include a first bobbin B1, a first coil C1, and a first pin (or a first terminal) P1.

The first bobbin B1 may include a first through-hole CH1 (or a first cavity) formed in the center thereof to allow the center leg CL of the core unit 110 to pass therethrough, and at least a portion of the first bobbin B1 may be accommodated inside the core unit 110.

The first coil C1 may be disposed in a first accommodation space SP1 in the first bobbin B1 and may be wound in multiple turns around the first through-hole CH1.

The first pin P1 is connected to the first coil C1 and serves as an input terminal (or an output terminal) of the transformer. To this end, the first pin P1 may include a 1-1^{st} pin P11 connected to an end C1E1 of the first coil C1 and a 1-2^{nd} pin P12 connected to the other end C1E2 of the first coil C1. Although the first pin P1 is illustrated as including two pins, the embodiments are not limited to any specific number of first pins P1.

The second coil unit 130A may include a second bobbin B2, a second coil C2, and a second pin (or a second terminal) P2.

The second bobbin B2 may include a second through-hole CH2 (or a second cavity) formed in the center thereof to accommodate at least a portion of the first bobbin B1 and may be disposed outside the first bobbin B1.

The second coil C2 may be disposed in a second accommodation space SP2 in the second bobbin B2 and may be wound in multiple turns around the first through-hole CH2.

The second pin P2 is connected to the second coil C2 and serves as an output terminal (or an input terminal) of the transformer. To this end, the second pin P2 may include a plurality of pins P21 to P24 connected to both ends of the second coil C2.

Although the second pin P2 is illustrated as including four pins, the embodiments are not limited to any specific number of second pins P2.

In this case, at least a portion of the first coil unit 120A may be disposed in the second through-hole CH2. Accordingly, the first coil unit 120A and the second coil unit 130A may at least partially overlap each other in the horizontal direction.

The first coil C1 and the second coil C2 may be multi-turn windings in which a rigid conductive metal, such as a copper wire, is wound in multiple turns in a spiral or planar spiral shape. However, the disclosure is not necessarily limited thereto. For example, the first coil C1 may employ an enameled wire (USTC wire) wrapped with fiber yarn, a Litz wire, or a triple insulated wire (TIW).

According to the embodiment, the first coil unit 120 (120A or 120B) may correspond to a primary coil of the transformer 100 (100A or 100B), and the second coil unit 130 (130A or 130B) may correspond to a secondary coil of the transformer 100 (100A or 100B). However, the disclosure is not necessarily limited thereto.

In addition, the diameter of the second coil C2 may be 0.7 to 0.9 times the height of the second bobbin B2 in a third direction. However, the disclosure is not necessarily limited thereto.

Hereinafter, the first bobbin B1 and the second bobbin B2 will be described in more detail with reference to FIGS. 5 and 6.

The first bobbin B1 according to an embodiment may include a first upper plate TP1, a first lower plate BP1, and a first sidewall portion SW1 disposed between the first upper plate TP1 and the first lower plate BP1. The first sidewall portion SW1 may define the first through-hole CH1 and may define the first accommodation space SP1, in which the first coil C1 is accommodated, together with the lower surface of the first upper plate TP1 and the upper surface of the first lower plate BP1.

The second bobbin B2 according to an embodiment may include a second upper plate TP2, a second lower plate BP2, and a second sidewall portion SW2 disposed between the second upper plate TP2 and the second lower plate BP2. The second sidewall portion SW2 may define the second cavity CH2 and may define the second accommodation space SP2, in which the second coil C2 is accommodated, together with the lower surface of the second upper plate TP2 and the upper surface of the second lower plate BP2.

Referring again to FIG. 4, a distance D1 between the outermost portion of the first coil C1 and the outer edge of the first bobbin B1 in the second direction from the first cavity CH1 toward the outer edge of the first coil unit 120 and a distance D2 between the outermost portion of the second coil C2 and the outer edge of the second bobbin B2 in the second direction from the second cavity CH2 toward the outer edge of the second coil unit 130 may be determined according to a minimum insulation distance required by a circuit in which the transformer 100 (100A or 100B) is disposed. That is, an empty space for ensuring an insulation distance is present in a portion of each of the first and second accommodation spaces SP1 and SP2 in the first and second bobbins B1 and B2 in which the first and second coils C1 and C2 are not disposed. Such an empty space hinders miniaturization of the transformer 100 (100A or 100B).

Therefore, according to the embodiment, an insulating filler may be embedded in the spaces in which the first and second coils C1 and C2 are not disposed in the first and second accommodation spaces SP1 and SP2 in the first and second bobbins B1 and B2, thereby enhancing insulation between the coils and between the coils and the core. As a result, the distances between the outermost portions of the coils C1 and C2 and the edges of the bobbins B1 and B2 may be reduced, whereby the transformer may be further miniaturized.

For better understanding, a portion between the center leg CL and one of the outer legs OL of the core unit 110, i.e., portion “A” in FIG. 4, is illustrated in detail in place of showing the entire structure of the transformer 100 (100A or 100B).

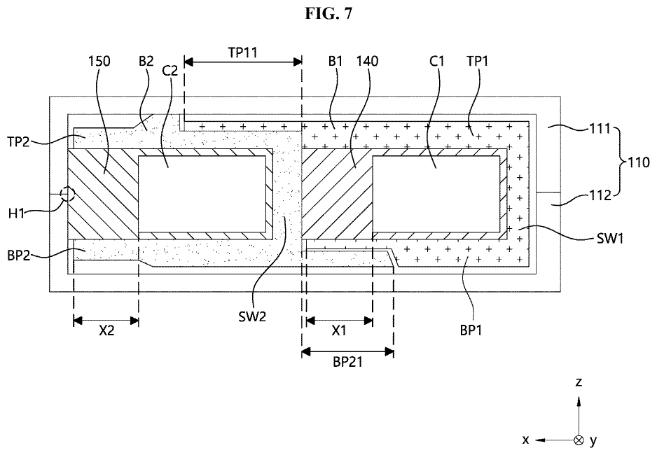

FIG. 7 is a view showing portion “A” in FIG. 4 in an enlarged manner.

To mainly describe the securing of insulation performance for the coils C1 and C2, the coils C1 and C2 are schematically represented in FIG. 7 as rectangular regions defined by lines extending in the third direction from the sidewall portions SW1 and SW2 to the outermost portions of the coils C1 and C2 in the accommodation spaces in the bobbins B1 and B2.

Referring to FIG. 7, the transformer 100 (100A or 100B) may further include first and second molding parts 140 and 150.

The first molding part 140 is disposed on the outer surface of the first coil unit 120. That is, the first molding part 140 may be disposed from a region in the first accommodation space SP1 in the first bobbin B1 in which the first coil C1 is disposed to the outer edge of the first bobbin B1.

The second molding part 150 is disposed on the outer surface of the second coil unit 130. That is, the second molding part 150 may be disposed from a region in the second accommodation space SP2 in the second bobbin B2 in which the second coil C2 is disposed to the outer edge of the second bobbin B2.

As such, the first molding part 140 may define the outer surface (i.e., outer circumferential surface) of the first coil unit 120, and the second molding part 150 may define the outer surface (i.e., outer circumferential surface) of the second coil unit 130.

For example, the first molding part 140 may be disposed between the second sidewall portion SW2 of the second bobbin B2 and the first coil C1.

Each of the first molding part 140 and the second molding part 150 may be formed of an insulating filler. Examples of the insulating filler may include a polymer resin-based material such as an epoxy resin. However, the insulating filler is not limited to any specific material, as long as the same is insulating and capable of maintaining a certain shape after injection.

The first molding part 140 may be formed by winding the first coil C1 on the first bobbin B1 and then injecting, i.e., injection-molding, the insulating filler into the first accommodation space SP1 in the first bobbin B1. However, the disclosure is not necessarily limited thereto.

Similarly, the second molding part 150 may be formed by winding the second coil C2 on the second bobbin B2 and then injecting, i.e., injection-molding, an insulating filler through a resin injection port (at least one of H1, H2, or H3, which will be described later). In this case, the injection of the insulating filler through the resin injection port may be performed after the first coil unit 120, in which the first molding part 140 has been formed, is coupled to the second cavity CH2. However, the disclosure is not necessarily limited thereto. This will be described in detail later.

In addition, in the transformer shown in FIG. 7, the upper plate TP1 of the first bobbin B1 may vertically overlap (denoted by TP11) the upper surface of the second bobbin B2, and the lower plate BP2 of the second bobbin B2 may vertically overlap (denoted by BP21) the lower surface of the first bobbin B1 and the first molding part 140.

By disposing the first molding part 140 and the second molding part 150, superior insulation performance may be achieved under the same spacing distance condition, compared to a configuration in which air is present between insulation targets, as shown in FIG. 4. Accordingly, a horizontal distance X1 required to satisfy an insulation distance in the first bobbin B1 may be reduced compared to the distance D1 in FIG. 4 while still satisfying insulation performance, and a horizontal distance X2 required to satisfy an insulation distance in the second bobbin B2 may also be reduced compared to the distance D2 in FIG. 4. Ultimately, since the horizontal distances required to secure insulation distances in the respective bobbins are reduced by disposing the first molding part 140 and the second molding part 150, the planar areas of the first coil unit 120 and the second coil unit 130 may be reduced, which indicates that the core unit 110 may also be miniaturized. Therefore, as the size of the magnetic element is reduced, the magnetic path also becomes shorter, which may contribute to a reduction in heat generation and an improvement in efficiency. In addition, since actual insulation distance requirements are satisfied, an increase in withstand voltage and an improvement in surge stability may also be expected.

Hereinafter, the resin injection port according to the embodiment through which the insulating filler is injected to form the second molding part 150 in the transformer 100 (100A or 100B) described above will be described with reference to the accompanying drawings.

Referring to FIGS. 2B and 3B, the second bobbin 130A or 130B may include a core area CA and a non-core area NCA.

The core area CA is defined as an area that vertically overlaps the core unit 110, and the non-core area NCA is defined as an area that does not vertically overlap the core unit 110.

The resin injection port H1, H2, and H3 according to the embodiment may be a molded or injection-molded region formed in the non-core area NCA, rather than in the core area CA, using a molding method or an injection molding method. Accordingly, the molded or injection-molded region corresponding to the region injection port H1, H2, and H3 may exhibit traces of resin injection, such as a recess, a hole, a protruding portion, or a worn region.

That is, the resin injection port may include a shape of a recess, a hole, or a protrusion.

In addition, the resin injection port may be formed with a surface roughness greater than that of a surrounding region on the outer surface of the second molding part 150.

The non-core area NCA may include a first non-core area NCA1 and a second non-core area NCA2.

The first non-core area NCA1 may be an area that is adjacent to a side 110P1 of the core unit 110 and is connected to the second pin P2. In addition, the second non-core area NCA2 may be an area that is adjacent to another side 110P2 of the core unit 110, opposite the side 110P1, and is connected to the first pin P1.

The first non-core area NCA1 and the second non-core area NCA2 may face each other with the core area CA interposed therebetween in the first direction intersecting the vertical direction.

The resin injection port may include at least one of a first resin injection port H1, a second resin injection port H2, or a third resin injection port H3. The first and third resin injection ports H1 and H3 may be disposed in the first non-core area NCA1, and the second resin injection port H2 may be disposed in the second non-core area NCA2.

If the first, second, or third resin injection port H1, H2, or H3 is disposed in the core area CA, a region in which the insulation distance requirements are not satisfied may be formed. For example, when the resin injection port is disposed in the core area CA, surges may be caused by the second coil C2. However, according to the embodiment, since the resin injection ports H1, H2, and H3 are disposed in the non-core area NCA, the surges may be mitigated, thereby improving robustness against surges.

If the resin injection port includes both the first and second resin injection ports H1 and H2, the first resin injection port H1 and the second resin injection port H2 may be disposed to face each other in an oblique direction on a plane, as shown in FIGS. 2B and 3B. However, the embodiments are not limited thereto.

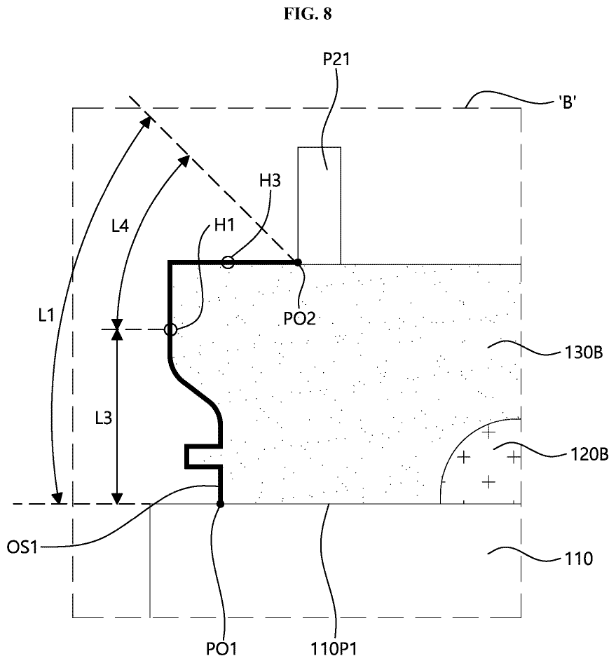

FIG. 8 is a view showing portion “B” in FIG. 3A in an enlarged manner.

Further, according to the embodiment, at least one of the first, second, or third resin injection port H1, H2, or H3 may be formed on the outer surface or the upper surface of the second bobbin 130A or 130B. For example, as shown in FIG. 6, the second resin injection port H2 may be formed on the outer surface of the second bobbin 130B.

As such, the first and second resin injection ports H1 and H2 may be formed on a side surface of the non-core area NCA, whereas the third resin injection port H3 may be disposed on a surface of the second bobbin B2 facing the protruding direction of the second pin P2.

In addition, the resin injection ports H1, H2, and H3 may horizontally overlap a region in which the upper core 111, the lower core 112, and the second molding part 150 are in contact with one another. For better understanding, the first resin injection port H1 is indicated by a dashed line in FIG. 7.

Each of the resin injection ports H1, H2, and H3 may include a plurality of recesses spaced apart from each other.

For better understanding, first and second outlines (or boundaries) OS1 and OS2 are highlighted by bold solid lines in FIGS. 2A, 3A, and 8.

According to the embodiment, a first path OS1, which defines the shortest distance, may be defined on a plane along the outer surface of the second bobbin B2 from a first point PO1, which is an outer point of the boundary 110P1 between the core area CA and the non-core area NCA, to a second point PO2, at which the second pin P2 protrudes outward from the second bobbin B2. The first resin injection port H1 may be disposed on the first path OS1 at a position closer to the second point PO2 than to the first point PO1.

Furthermore, the first resin injection port H1 may be disposed on the first path OS1 at a position spaced apart from the first point PO1 by at least half of the length of the first path OS1.

According to the embodiment, the first resin injection port H1 may be disposed to be spaced apart from the side 110P1 of the core unit 110 by at least half of the overall length (hereinafter referred to as a “first length”) L1 of the first outline OS1 on the planar surface of the second bobbin B2, which is located between the side 110P1 of the core unit 110 and the second pin P2.

In addition, the second resin injection port H2 may be disposed to be spaced apart from the opposite side 110P2 of the core unit 110 by at least half of the overall length (hereinafter referred to as a “second length”) L2 of the second outline OS2 on the planar surface of the second bobbin B2, which is located between the opposite side 110P2 of the core unit 110 and the first pin P1.

A length (hereinafter referred to as a “third length”) L3 from the first resin injection port H1 to the side 110P1 of the core unit 110 along the first outline OS1 may be determined using Equation 1 below.

$$L 3 \geq \frac{L 1}{2} \qquad [ Equation 1 ]$$

When the first resin injection port H1 is disposed at a position that satisfies Equation 1 above, the transformer may be more robust against surges caused by the second coil C2 than when the first resin injection port H1 is disposed at a position that does not satisfy Equation 1.

In addition, when a length from the first resin injection port H1 to the second pin P2 along the first outline OS1 is defined as a fourth length L4, the third length L3 may be greater than or equal to the fourth length L4. When the third length L3 is greater than or equal to the fourth length L4, the transformer may be more robust against surges caused by the second coil C2 or the core unit 110 than when the third length L3 is less than the fourth length L4.

A length (hereinafter referred to as a “fifth length”) L5 from the second resin injection port H2 to the opposite side 110P2 of the core unit 110 along the second outline OS2 may be determined using Equation 2 below.

$$L 5 \geq \frac{L 2}{2} \qquad [ Equation 2 ]$$

When the second resin injection port H2 is disposed at a position that satisfies Equation 2 above, the transformer may be more robust against surges caused by the second coil C2 or the core unit 110 than when the second resin injection port H2 is disposed at a position that does not satisfy Equation 2.

In addition, when a length from the second resin injection port H2 to the first pin P1 along the second outline OS2 on the plane is defined as a sixth length L6, the fifth length L5 may be greater than or equal to the sixth length L6. When the fifth length L5 is greater than or equal to the sixth length L6, the transformer may be more robust against surges caused by the second coil C2 or the second core unit 110 than when the fifth length L5 is less than the sixth length L6.

According to the embodiment, each of the first and second lengths L1 and L2 may be 8 mm or greater. In this case, each of the third to sixth lengths L3 to L6 may be 4 mm or greater.

According to the embodiment, each of a distance from the first point PO1 to the first resin injection port H1 along the first path OS1 and a distance from the first resin injection port H1 to the second point PO2 along the first path may be 4 mm or greater.

Surges introduced through the second pin P2 (or the first pin P1) may be mitigated when the first length L1 (or the second length L2) is 8 mm or greater. Furthermore, when the fourth length L4 (or the sixth length L6) is 4 mm or greater, the transformer may be more robust against surges introduced through the second pin P2 (or the first pin P1).

In addition, at least one of the first or second non-core area NCA1 or NCA2 may include a neighboring area and a non-neighboring area. Referring to FIG. 3B, the first non-core area NCA1 may include a neighboring area NA1 and a non-neighboring area NNA1, and the second non-core area NCA2 may include a neighboring area NA2 and a non-neighboring area NNA2.

The neighboring areas NA1 and NA2 are defined as areas in the non-core areas NCA1 and NCA2 that are adjacent to the core unit 110, and the non-neighboring areas NNA1 and NNA2 are defined as areas in the non-core areas NCA1 and NCA2 that are spaced farther from the core unit 110 than the neighboring areas NA1 and NA2.

Referring to FIGS. 3B and 8, in the second direction intersecting both the vertical direction and the first direction, a first width W1 of the neighboring areas NA1 and NA2 may be less than a second width W2 of the non-neighboring areas NNA1 and NNA2.

In addition, at least one of the first outline OS1 or the second outline OS2 may protrude farther outward in the second direction in the non-neighboring area NNA1 or NNA2 than in the neighboring area NA1 or NA2. For example, as shown in FIG. 3B, both the first outline OS1 and the second outline OS2 may protrude farther outward in the second direction in the non-neighboring areas NNA1 and NNA2 than in the neighboring areas NA1 and NA2.

When the transformer 100 (100A or 100B) includes the first and second molding parts 140 and 150, insulation performance may be additionally secured without increasing the planar area of the transformer, thereby allowing the size of the transformer in the horizontal direction to be reduced. However, as the size of the transformer in the horizontal direction increases, it may become difficult for the positions of the first and second resin injection ports H1 and H2 to satisfy Equation 1 or 2 described above. To address this, as shown in FIG. 3B, when the non-neighboring areas NNA1 and NNA2 protrude farther outward in the second direction than the neighboring areas NA1 and NA2, or when the second width W2 is greater than the first width W1, the first and second lengths L1 and L2 may be increased compared to the configuration shown in FIG. 2B. As a result, it may become easier to satisfy Equation 1 or 2 described above, even when the size of the transformer in the horizontal direction is reduced.

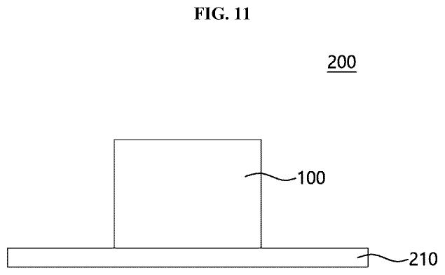

In addition, when the non-neighboring areas NNA1 and NNA2 protrude farther outward in the second direction than the neighboring areas NA1 and NA2, or when the second width W2 is greater than the first width W1, the transformer may be guided by the protruding portions when the transformer is placed on a substrate 210, which will be described later with reference to FIG. 11.

Hereinafter, a method of manufacturing the transformer according to an embodiment will be described with reference to the accompanying drawings.

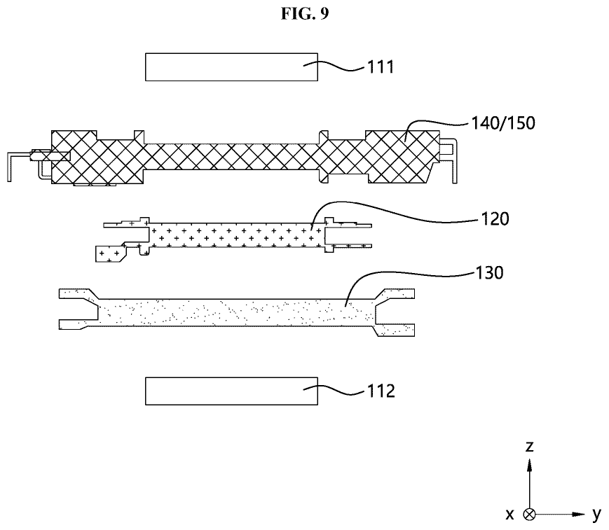

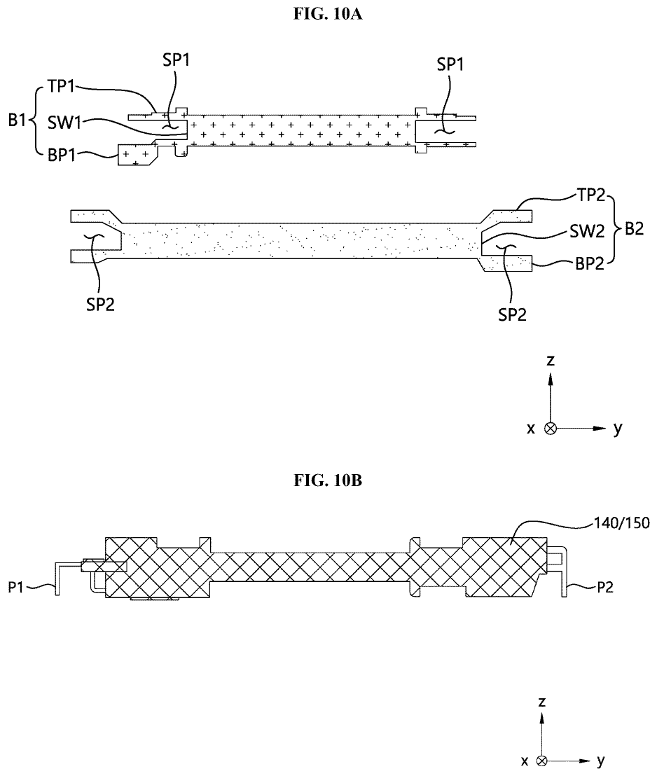

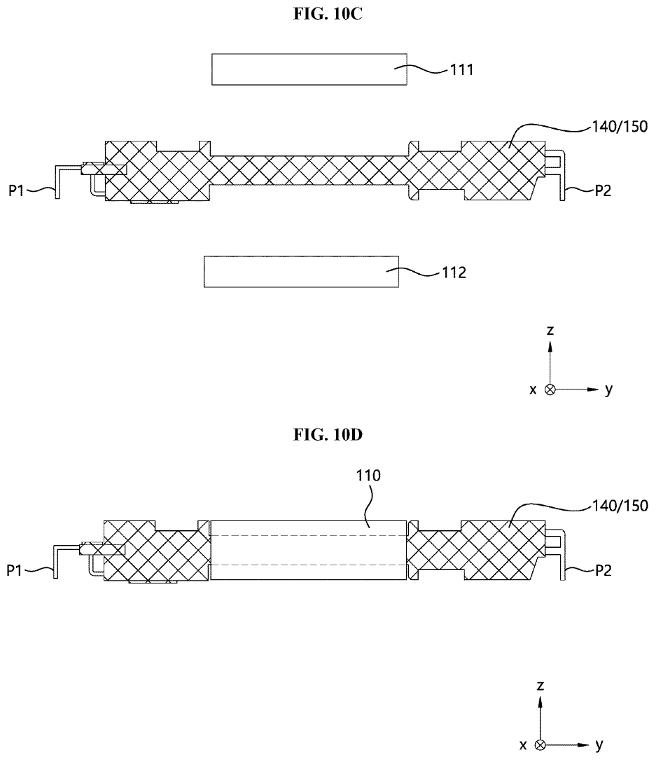

FIG. 9 is an exploded side view of the transformer 100 (100A or 100B) according to the above-described embodiment, and FIGS. 10A to 10D are side views showing processes of manufacturing the transformer 100 (100A or 100B) according to an embodiment.

Since the transformer shown in FIGS. 9 and 10A to 10D is identical to the transformer 100 (100A or 100B) described above, the same parts are denoted by the same reference numerals, and redundant descriptions thereof will be omitted.

First, as shown in FIG. 10A, the first bobbin B1 and the second bobbin B2 are prepared.

Subsequently, the first coil C1 is wound around the first bobbin B1 shown in FIG. 10A, and the first molding part 140 is formed.

Subsequently, the second coil C2 is wound around the second bobbin B2 shown in FIG. 10A, and the first bobbin B1, around which the first coil C1 is wound, is assembled to the second bobbin B2, around which the second coil C2 is wound.

Subsequently, an insulating filler is injected through the above-described resin injection ports H1, H2, and H3 to form the second molding part 150. For example, when the insulating filler is injected through the resin injection port H2 shown in FIG. 6, the second molding part 150 may be formed in an empty space not occupied by the second coil C2 in the second accommodation space SP2, as shown in FIGS. 7 and 10B.

Subsequently, the upper core 111 and the lower core 112 shown in FIG. 10C are respectively assembled to an upper side and a lower side of the assembly shown in FIG. 10B, thereby completing the manufacture of the transformer, as shown in FIG. 10D.

Furthermore, as described above, the transformer 100A or 100B according to the embodiment may constitute a circuit board that constitutes a power supply unit (PSU) together with other magnetic elements (e.g., an inductor).

Hereinafter, a circuit board 200 according to an embodiment, which includes the above-described transformer, will be described with reference to the accompanying drawings.

FIG. 11 is a side view of the circuit board 200 according to the embodiment.

The circuit board 200 shown in FIG. 11 may include a substrate (or a printed circuit board (PCB)) 210 and a transformer 100.

The transformer 100 is disposed on the substrate 210. Since the transformer 100 corresponds to the transformers 100A and 100B according to the above-described embodiments, redundant description thereof will be omitted.

While the present disclosure has been particularly shown and described with reference to exemplary embodiments thereof, these embodiments are only proposed for illustrative purposes, and do not restrict the present disclosure, and it will be apparent to those skilled in the art that various changes in form and detail may be made without departing from the essential characteristics of the embodiments set forth herein. For example, respective configurations set forth in the embodiments may be modified and applied. Further, differences in such modifications and applications should be construed as falling within the scope of the present disclosure as defined by the appended claims.

### MODE FOR DISCLOSURE

Various embodiments have been described in the best mode for carrying out the disclosure.

### INDUSTRIAL APPLICABILITY

The magnetic element and the circuit board including the same according to the embodiments may be used in a power supply unit of an electronic device or the like.

1. A magnetic element, comprising:
a core unit including an upper core and a lower core;
a first coil unit and a second coil unit, each being at least partially accommodated between the upper core and the lower core; and
a second molding part disposed on an outer surface of the second coil unit,
wherein the first coil unit includes:
a first bobbin including a first cavity formed therein to allow a center leg of the core unit to pass therethrough, the first bobbin being at least partially accommodated inside the core unit;
a first coil disposed in a first accommodation space in the first bobbin; and
a first pin connected to the first coil,
wherein the second coil unit includes:
a second bobbin including a second cavity formed therein to accommodate at least a portion of the first bobbin, the second bobbin being disposed outside the first bobbin;
a second coil disposed in a second accommodation space in the second bobbin; and
a second pin connected to the second coil, and
wherein the second bobbin includes:
a core area overlapping the core unit in a vertical direction;
a non-core area not overlapping the core unit in the vertical direction; and
a recess formed in the non-core area.

2. The magnetic element according to claim 1, wherein the recess is formed in a side surface of the non-core area.

3. The magnetic element according to claim 1, wherein the non-core area includes:
a first non-core area adjacent to one side of the core unit and connected to the second pin; and
a second non-core area adjacent to another side of the core unit, opposite the one side, and connected to the first pin, and
wherein the recess includes at least one of:
a first recess disposed in the first non-core area; or
a second recess disposed in the second non-core area.

4. The magnetic element according to claim 3, wherein each of the first recess and the second recess includes a plurality of recesses spaced apart from each other.

5. The magnetic element according to claim 3, wherein the first recess and the second recess are disposed to face each other in an oblique direction on a plane.

6. The magnetic element according to claim 3, wherein a first path defining a shortest distance is defined on a plane along an outer surface of the second bobbin from a first point to a second point, the first point being an outer point of a boundary between the core area and the non-core area, and the second point being a point defined by outward protrusion of the second pin from the second bobbin, and
wherein the first recess is disposed on the first path at a position closer to the second point than to the first point.

7. The magnetic element according to claim 3, wherein a first path defining a shortest distance is defined on a plane along an outer surface of the second bobbin from a first point to a second point, the first point being an outer point of a boundary between the core area and the non-core area, and the second point being a point defined by outward protrusion of the second pin from the second bobbin, and
wherein the first recess is disposed on the first path at a position spaced apart from the first point by at least half of a length of the first path.

8. The magnetic element according to claim 1, wherein the recess is disposed on a surface of the second bobbin facing a protruding direction of the second pin.

9. The magnetic element according to claim 3, wherein the first recess is formed in an outer surface or an upper surface of the second bobbin.

10. A circuit board, comprising:
a substrate; and
a magnetic element disposed on the substrate,
wherein the magnetic element includes:
a core unit including an upper core and a lower core;
a first coil unit and a second coil unit, each being at least partially accommodated between the upper core and the lower core; and
a molding part disposed on an outer surface of the second coil unit,
wherein the first coil unit includes:
a first bobbin including a first cavity formed therein to allow a center leg of the core unit to pass therethrough, the first bobbin being at least partially accommodated inside the core unit;
a first coil disposed in a first accommodation space in the first bobbin; and
a first pin connected to the first coil,
wherein the second coil unit includes:
a second bobbin including a second cavity formed therein to accommodate at least a portion of the first bobbin, the second bobbin being disposed outside the first bobbin;
a second coil disposed in a second accommodation space in the second bobbin; and
a second pin connected to the second coil, and
wherein the second bobbin includes:
a core area overlapping the core unit in a vertical direction; and
a non-core area not overlapping the core unit in the vertical direction, the non-core area including a resin injection port formed therein.

11. The magnetic element according to claim 6, wherein a length of the first path is 8 mm or greater.

12. The magnetic element according to claim 11, wherein each of a distance from the first point to the first recess along the first path and a distance from the first recess to the second point along the first path is 4 mm or greater.

13. The magnetic element according to claim 1, wherein the first bobbin includes:
a first upper plate;
a first lower plate; and
a first sidewall portion disposed between the first upper plate and the first lower plate, the first sidewall portion defines a first accommodation space together with a lower surface of the first upper plate and an upper surface of the first lower plate, and
wherein the second bobbin includes:
a second upper plate;
a second lower plate; and
a second sidewall portion disposed between the second upper plate and the second lower plate, the second sidewall portion defines the second accommodation space together with a lower surface of the second upper plate and an upper surface of the second lower plate.

14. The magnetic element according to claim 13, comprising a first molding part disposed between the second sidewall portion of the second bobbin and the first coil.

15. The magnetic element according to claim 14, wherein each of the first molding part and the second molding part includes an insulating filler.

16. The magnetic element according to claim 14, wherein the upper plate of the first bobbin vertically overlaps an upper surface of the second bobbin, and
wherein the lower plate of the second bobbin vertically overlaps each of a lower surface of the first bobbin and the first molding part.

17. The magnetic element according to claim 14, wherein the first and second molding parts are disposed in spaces in which the first and second coils are not disposed.

18. The magnetic element according to claim 10, wherein the resin injection port includes a shape of a recess, a hole, or a protrusion.

19. The magnetic element according to claim 10, wherein the resin injection port is formed with a surface roughness greater than a surface roughness of a surrounding region on an outer surface of the molding part.

20. The magnetic element according to claim 10, wherein the resin injection port horizontally overlaps a region in which the upper core, the lower core, and the molding part are in contact with one another.
